(19) United States
(12) Patent Application Publication
(10) Pub. No.: US 2026/0031826 A1
(43) Pub. Date: Jan. 29, 2026

(54) NOISE REDUCTION SYSTEM AND METHOD

(71) Applicant: Analog Devices International Unlimited Company, Limerick (IE)

(72) Inventors: Gabriel Banarie, Murroe (IE); Jakub Franek, Brno (CZ); Kalin V. Lazarov, Colorado Springs, CO (US); Rodney Morgia Manalo, Cavite (PH)

(21) Appl. No.: 18/781,634

(22) Filed: Jul. 23, 2024

(51) Int. Cl. H03M 1/06; H03M 1/10

(52) U.S. Cl. CPC H03M 1/0626; H03M 1/1009

(57) ABSTRACT

There is provided systems for and methods of generating of an adjusted output signal. The method may include: providing an unadjusted voltage reference; receiving at least one of a first calibrated voltage based on a base-emitter voltage of one or more pnp transistors, a second calibrated voltage based on a base-emitter voltage of one or more npn transistors, and a voltage that is proportional to absolute temperature; determining a digital estimate of the output signal based on an analog representation of the output signal, and based on the at least one of the first calibrated voltage, the second calibrated voltage, and the voltage that is proportional to absolute temperature; deriving an error in the digital estimate of the output signal based on a difference between the digital estimate of output signal and an ideal digital output signal; and combining the error in the digital estimate of the output signal with the unadjusted voltage reference in order to generate the adjusted output signal.

### FIELD

This application relates to methods and systems for noise reduction and, in particular but not exclusively, to methods and systems for low frequency noise reduction in a voltage reference.

### BACKGROUND

Voltage reference circuits are typically used in systems that require a voltage reference that is relatively accurate and stable. However, performance of electronic circuits including voltage reference circuits may be affected by temperature, mechanical stresses and 1/f noise that can be problematic for achieving high accuracy of an analog-to-digital converter (ADC).

Temperature and mechanical stress variations may be compensated for by finding a temperature coefficient and correcting a conversion result using look up tables based on known properties of pnp and npn transistors, respectively. Further, in data converters and, more generally, in electronic circuits which operate in discrete time domain, 1/f noise is generally removed through chopping and/or auto-zero techniques. However, most voltage reference generators operate in continuous time; therefore, the above methods are unavailable for removing 1/f noise.

### SUMMARY OF THE DISCLOSURE

Therefore, it is desirable to reduce variations due to external stimuli such as temperature and mechanical stresses as well as mitigate 1/f noise and the impact of low frequency noise on the voltage reference of electronic circuits such as bandgap reference circuits, Zener reference circuits and flip-gate reference circuits.

The systems and methods of the present disclosure provide ways in which to reduce 1/f noise or low frequency noise at the voltage reference by generating an adjusted output signal. This technique may be combined with other techniques to reduce variations of the voltage reference due to external factors, such as temperature and mechanical stress, and with other techniques to filter noise in order to provide an accurate and reliable voltage reference.

In one aspect of the present disclosure, there is provided a method of generating of an adjusted output signal. The method comprises: providing an unadjusted voltage reference; receiving at least one of a first calibrated voltage based on a base-emitter voltage of one or more pnp transistors, a second calibrated voltage based on a base-emitter voltage of one or more npn transistors, and a voltage that is proportional to absolute temperature; determining a digital estimate of the output signal based on an analog representation of the output signal, and based on the at least one of the first calibrated voltage, the second calibrated voltage, and the voltage that is proportional to absolute temperature; deriving an error in the digital estimate of the output signal based on a difference between the digital estimate of output signal and an ideal digital output signal; and combining the error in the digital estimate of the output signal with the unadjusted voltage reference in order to generate the adjusted output signal.

In the method of providing accurate and reliable voltage references, by generating a digital estimate of an analog output signal, calculating the error in this estimate relative to an ideal output signal and based on a calibrated voltage signal, and then adjusting the analog output signal by combining an unadjusted voltage reference with this error, a more accurate and reliable output signal can be produced.

The calibrated voltage signal is selected from 1) a voltage based on the characteristics of a pnp transistor (VCAL_PNP); 2) a voltage based on the characteristics of a npn transistor (VCAL_NPN); and 3) a voltage that is dependent upon and changes with temperature (VPTAT).

The PTAT voltage is directly proportional to the absolute temperature (T) and can be expressed as:

$$V PTAT = k \cdot T$$

where:
k is temperature coefficient; and
T is the absolute temperature in Kelvin.

The voltage that is dependent upon and changes with temperature is a voltage that is proportional to absolute temperature. Said voltage may be based on base-emitter voltage of two or more of the same type of transistors, pnp or npn. The two transistors of the same type may be operating at different current densities. Base-emitter voltage pnp or npn transistors change with absolute temperature.

$${V}_{PTAT} = {V}_{BE 1} - {V}_{BE 2}$$

Bandgap reference circuits can also be used to generate PTAT voltages by combining base-emitter voltages of pnp and npn transistors with voltages from other components such as resistors or diodes.

There are also other means of generating PTAT voltages, for example, using a Zener diode. A Zener diode operates in the reverse breakdown region, maintaining a constant voltage drop across its terminals. The voltage across a Zener diode is approximately proportional to absolute temperature:

$${V}_{PTAT} = {V}_{2} \cdot ( 1 + \frac{T}{{T}_{0}} )$$

where T₀ is a reference temperature (usually room temperature).

Using just one of the calibrated voltage signals, variations in the output voltage of the circuit can be tracked and therefore the voltage reference can be adjusted to correct for errors and to improve its accuracy. Thus, output voltage adjustment can be achieved.

In some examples, both VPTAT and one of VCAL_PNP and VCAL_NPN are used. In this case, in addition to tracking variations in the output voltage, variations in temperature can also be tracked. Thus, output voltage adjustment as well as temperature compensation can be achieved.

In some examples, each of VPTAT, VCAL_PNP and VCAL_NPN are used. In the case, in addition to tracking variations in the output voltage and temperature, variations in mechanical stress can also be tracked. Thus, output voltage adjustment as well as temperature and mechanical stress compensation can be achieved.

In some examples, an iterative algorithm may be used to estimate the output signal. An iterative algorithm is a process that repeats its operation until a convergence in the output voltage or any other output of the circuit occurs. For example, the iterative algorithm may produce a digital code that is used to adjust the analog representation of the output signal to match the ideal output signal. In another example, the estimate for temperature might be monitored for determining convergence.

In other examples, a single step algorithm may be used to estimate the output signal. Unlike an iterative algorithm, a single step algorithm performs its operation only once.

In some examples, applying a low pass filter to the unadjusted voltage reference may allow only signals with a frequency lower than a certain cutoff frequency to pass through and therefore removes high-frequency noise from the unadjusted voltage reference. The low pass filter may be coupled in cascade with the unadjusted voltage reference generator and configured to remove noise aliasing from unadjusted voltage reference.

In some examples, a first order integration process may be used to shape the noise profile of the adjusted output signal. First order integration is a mathematical process that can reduce the impact of noise on the signal. It may be applied to the error in the digital estimate of the output signal which is then to be combined with the unadjusted reference generator, which may be filtered in order to remove noise aliasing from the unadjusted voltage reference.

In some examples, a second order or higher order integration process may be used to shape the noise profile of the adjusted output signal. Higher order integration can provide more advanced noise shaping, potentially leading to a cleaner output signal.

In one aspect of the present disclosure, there is provided a circuit for generating an adjusted output signal. The circuit comprises a calibration circuit providing at least one of a first calibrated pnp voltage based on a base-emitter voltage of one or more pnp transistors, a second calibrated npn voltage based on a base-emitter voltage of one or more npn transistors, and a voltage that is proportional to absolute temperature. The circuit also comprises an analog-to-digital converter, ADC, system coupled to the calibration circuit, and configured to: determine a digital estimate of the output signal based on an analog representation of the output signal, and based on the at least one of the first calibrated voltage, the second calibrated voltage, and the voltage that is proportional to absolute temperature; and derive an error in the digital estimate of the output signal based on a difference between the digital estimate of output signal and an ideal digital output signal. The circuit also comprises a digital-to-analog converter, DAC, configured to output an analog representation of the error. The circuit also comprises an unadjusted voltage reference generator configured to generate an unadjusted voltage reference that is combined together with the output of the DAC in order to generate the adjusted output signal.

In the system for providing accurate and reliable voltage references according to the present disclosure, a circuit for generating an adjusted output signal includes a calibration circuit, an ADC system, a digital-to-analog converter (DAC) and an unadjusted voltage reference generator.

The calibration circuit generates and outputs three main calibrated voltages based on the voltage inputs. The three main calibrated voltages are: 1) a voltage based on the characteristics of a pnp transistor (VCAL_PNP); 2) a voltage based on the characteristics of a npn transistor (VCAL_NPN); and 3) a voltage that is dependent upon and changes with temperature (VPTAT). These three main calibrated voltages are then used as inputs for the rest of the circuit.

The ADC system converts analog signals (continuous signals) into the digital domain (binary, 0s and 1s). It uses actual analog output signal, which could be used as a voltage reference, together with at least one of the calibrated voltages from the calibration circuit in order to estimate the output signal in a digital format. It also calculates how much this estimate deviates from an ideal output.

The DAC takes the error calculated by the ADC system and converts it back into an analog signal.

The unadjusted voltage reference generator is a constant voltage source that provides a continuous unadjusted analog voltage (or seed voltage). However, this voltage is not adjusted for errors introduced by variations in external stimuli, including, but not limited to temperature and mechanical stresses as well as 1/f noise. The unadjusted seed voltage is combined with the output of the DAC such that an adjusted output signal is provided by correcting the unadjusted seed voltage with the error information. The result of the feedback loop is an adjusted analog voltage output that can be used as an accurate reliable voltage reference.

Fundamentally, the calibration circuit provides one of the calibrated voltage signals, and using said information from said calibrated voltage signal, variations in the output voltage of the circuit can be tracked and therefore the voltage reference can be adjusted to correct for errors and to improve its accuracy. Thus, output voltage adjustment can be achieved.

In some examples, the calibration circuit may provide both the VPTAT voltage and one of VCAL_PNP and VCAL_NPN voltages. In this case, in addition to tracking variations in the output voltage, variations in temperature can also be tracked. Thus, output voltage adjustment can be achieved. Further, temperature tracking and compensation of variations of the calibration circuit can be achieved; the circuit may also estimate the temperature of the calibration circuit.

In some examples, the calibration circuit may provide all three types of voltages, i.e. each of the VPTAT, VCAL_PNP and VCAL_NPN. In the case, in addition to tracking variations in the output voltage and temperature, variations in mechanical stress can also be tracked. Thus, output voltage adjustment can be achieved. Further, temperature tracking and compensation of variations of the calibration circuit can be achieved; the circuit may also estimate the temperature of the calibration circuit. Yet further, mechanical stress compensation due to any exposure to stress of the calibration circuit may be achieved.

In some examples, the ADC system may include a multiplexer, which is a device can select between different input signals. In this case, it selects between the first calibrated pnp voltage, the second calibrated npn voltage and the voltage that is proportional to absolute temperature. The selected signal may then converted into a digital estimate by an ADC, which also generates a digital estimate of an analog representation of the output signal.

In other examples, the ADC system may include, alternatively to the multiplexer, which routes multiple input channels to a single ADC, a plurality of ADCs in parallel. The use of a plurality of ADCs may increase the overall sampling rate of the ADC system.

Once the digital estimate of the analog signal selected by the multiplexer, and the digital estimate of the analog representation of the output signal have been derived by the ADC(s), a digital estimate of the output signal is found. An error in the digital estimate of the output signal based on a difference between the digital estimate of output signal and an ideal digital output signal may be found, for example, by the ADC.

In some examples, the ADC system may include a separate processor that performs computations to produce the error. The processor may be configured to determine the digital estimate of the output signal based on the digital estimate of the analog signal selected by the multiplexer and the digital estimate of the analog representation of the output signal.

The digital algorithm for producing the error may be computed by the ADC or by the processor. The digital algorithm may be an iterative algorithm, for example, an iterative algorithm that produces a digital code that is used to adjust the analog representation of the output signal to match the ideal output signal, or the digital algorithm may be a single step algorithm.

In some examples, the circuit may include a low pass filter, which may allow signals with a frequency lower than a certain cutoff frequency to pass through and therefore removes high-frequency noise from the unadjusted voltage reference.

In some examples, the circuit may include a digital integrator that performs integration on digital signals. This is advantageous in shaping the noise profile of the adjusted output signal. The bandpass of the low pass filter may be an order of magnitude lower than the update rate of the DAC, such that the low pass filter allows a narrower range of frequencies to pass through, which can result in further reduction of noise.

In some examples, the circuit may include an adder that combines a plurality of signals. In this case, it can combine the output of the DAC and the unadjusted voltage reference in order to generate the adjusted output signal.

### Definitions

‘1/f noise’ or ‘pink noise’ is noise having a power spectral density that is inversely proportional to the frequency of the signal. Therefore, 1/f noise is higher at lower frequencies than at higher frequencies.

The 1/f noise region or ‘low frequency noise’ may be defined as all frequencies below an inflexion point frequency, above which the noise spectral power density is flat relative to frequency, for example, it could be in the bandwidth 0.1 Hz to 10 Hz (specified as a peak-to-peak voltage) and ‘wide band noise’ or ‘broadband noise’ may be defined as, for example, in the bandwidth 10 Hz to 1 kHz (specified as RMS voltage). The total noise of a system may be defined as the combination of low frequency noise and broadband noise.

The ‘voltage reference’ refers to an adjusted voltage reference, i.e. a constant DC voltage output that is unaffected by external factors such as temperature, mechanical stresses and 1/f noise, whereas the ‘seed voltage reference’ refers to an unadjusted voltage reference.

### BRIEF DESCRIPTION OF THE DRAWINGS

Aspects of the present disclosure are described, by way of example only, with reference to the following drawings, in which:

FIG. 1 shows a graph indicating noise present at the output of a voltage reference generator;

FIG. 2 is a schematic representation of a system for reducing low frequency noise;

FIG. 3 is a schematic representation of a system for reducing low frequency noise in accordance with an aspect of the present disclosure;

FIG. 4 is a schematic representation of a control loop implementation in accordance with an aspect of the present disclosure;

FIG. 5 shows graphs of example output signals in accordance with an aspect of the present disclosure;

FIG. 6 shows graphs of example output signals in accordance with an aspect of the present disclosure; and

FIG. 7 represents example method steps according to an aspect of the present disclosure.

### DETAILED DESCRIPTION

A voltage reference used to generate signals may be sensitive to temperature and mechanical stress as well as affected by noise (including thermal noise, 1/f noise, drift, etc.). Therefore, any absolute analog signal that is generated will be a function of all three of these factors. Of these three factors, temperature may impact the accuracy of the voltage reference the most, then mechanical stresses, and then 1/f noise.

For temperature variations caused by drift, the temperature coefficient can be calculated as an average drift over the operational temperature range of the voltage reference, and used in a temperature compensation circuit that adjusts the voltage reference based on measured temperatures.

For mechanical stress variations, it is known that pnp and npn transistors respond differently to mechanical stress, but the ratio of these responses is a function of temperature only, i.e. the ratio does not depend on the actual amount of stress applied. The pnp and npn transistor responses can be converted to the digital domain for processing, and two independent ADC conversions can be used to determine temperature and mechanical stress variations.

For noise variations, the effect of wide-band noise (e.g. above 10 Hz) may be mitigated through filtering. Further, the effect of slow noise may be mitigated through discrete time techniques (e.g. chopping or auto-zeroing). However, since voltage reference generators typically operate in continuous time rather than discrete time, chopping or auto-zeroing cannot be used to remove 1/f noise.

As described in the background section, it is desirable to reduce variations due to temperature and mechanical stresses as well as mitigate 1/f noise, which is indistinguishable from short to medium term drift at the low end of the frequency spectrum, and reduce the impact of low frequency noise on the voltage reference. By mitigating 1/noise, an advantage is that system performance can be improved for signal chains processing absolute (as opposed to ratiometric) analog quantities, reliant on unchanging voltage references. A further advantage is the ability to shape in frequency, with a high-pass profile, the noise profile of a voltage reference generator. Such a system would benefit from any low-pass noise-limiting filters which may be attached to the output of the voltage reference generator.

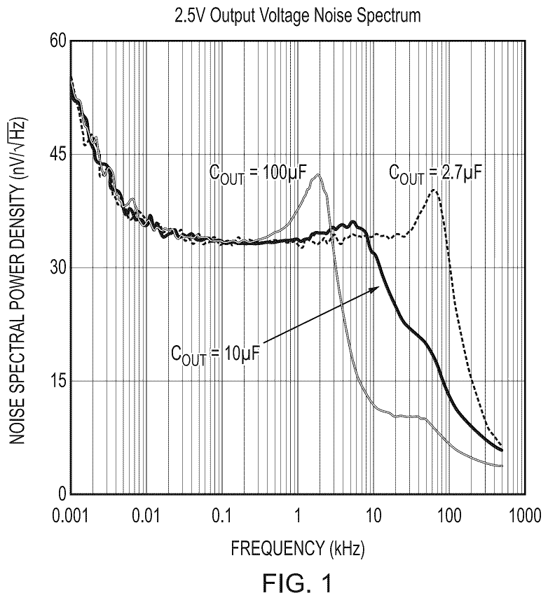

FIG. 1 shows a typical noise profile of a state of the art voltage reference generator across a frequency spectrum. Along the x-axis is frequency on a logarithmic scale from 0.001 kHz to 1000 kHz and along the y-axis is noise spectral power density in nV/√Hz on a linear scale from 0 to 60 nV/√Hz. Three options are shown for the output capacitance. The red line represents the noise spectrum for C_{OUT}=100 μF. The blue line represents the noise spectrum for C_{OUT}=10 ρF. The green line represents the noise spectrum for C_{OUT}=2.2 μF. Typically, as the value of C_{OUT} increases, the noise voltage decreases. However, as it can be seen, low pass filtering (for each of the three options are shown) has little or no impact on the low frequency noise.

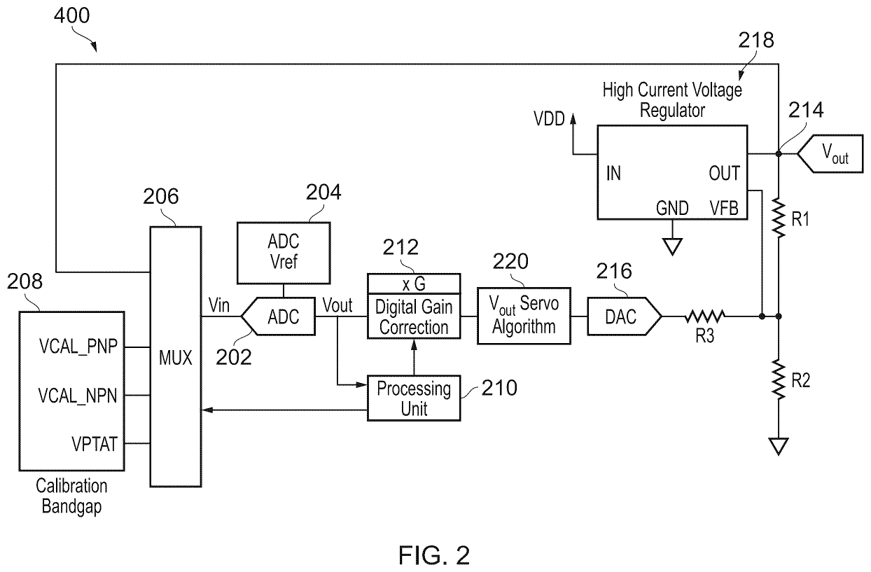

FIG. 2 shows a compensated regulator, which requires two separate voltage reference generators: a first one labelled 204 and a second one embedded in 218.

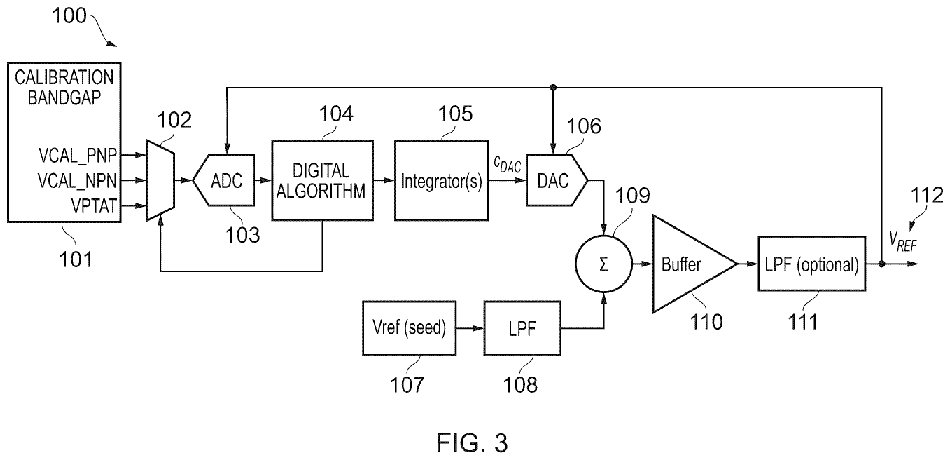

System 400 corrects an output voltage of a regulator due to stress-impaired signals introduced into a regulator, according to various aspects of the present disclosure. As described with respect to FIGS. 2 and 3, system 400 includes an ADC 202, a Vref 204, a multiplexer (MUX) 206, a calibration circuit 208, a processing unit 210, and a digital gain correction buffer 212.

System 400 also includes a digital-to-analog converter (DAC) 216 and voltage regulator circuit 218.

System 400 is coupled to regulator circuit 218 to correct the output Vout of the regulator circuit. In the depicted example, multiplexer 206 is connected to calibration circuit 208 and regulator output voltage Vout as a sense terminal 214, and configured to provide an analog signal selected from one of regulator output voltage Vout, the first calibrated pnp voltage Vcal_pnp, and the second calibrated npn voltage Vcal_npn.

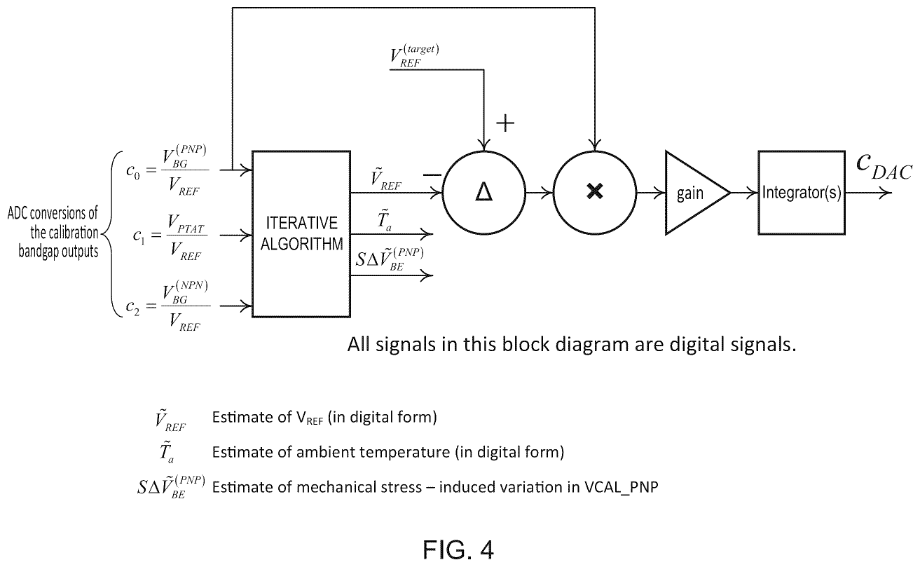

In the depicted example, DAC 216 receives the corrected output of ADC 202 based on a servo loop control algorithm 220. Algorithm 220 controls the sequencing, timing, and computational capabilities of a servo loop. In some implementations, servo loop control algorithm 220 is executed by processing unit 210. In some implementations the algorithm is implemented in a servo loop controller (at reference 220 in FIG. 4), positioned between ADC 202 and DAC 216 to receive the corrected output of ADC 202. The output of ADC 202 or digital servo controller 220 is converted to analog form by a DAC 216, and is further provided to regulator circuit 218 as a reference voltage. In some implementations, the precision of the digital to analog conversion is due to a relatively slow servo loop. The voltage regulator is configured, by way of the servo loop, to handle fast output transients and load/line regulation.

FIG. 3 shows an arrangement in accordance with the present disclosure of circuit that generates an adjusted output signal suitable for use as an accurate and reliable voltage reference, including a calibration circuit 101, an ADC system 102, 103, a DAC 106 and an unadjusted voltage reference generator 107.

In the circuit of FIG. 3, a calibration circuit 101 outputs three calibration signals, VCAL_PNP, VCAL_NPN and VPTAT, to a multiplexer 102, which selects at least one of said calibration signals for inputting into the ADC 103. The output voltage 112 of the circuit is also fed into the ADC 103. A digital algorithm block 104 processes the digital signals from the ADC 103. A digital integrator 105 to implement a first order control loop is shown in FIG. 3, although it will be appreciated that digital integrators implementing second or higher order control loops also fall within the scope of the present disclosure. The processed signals from the digital integrator 105 are converted back to analog format by the DAC 106 and an adder 109 combines the output of the DAC 106 with a seed voltage reference 107, which is an unadjusted voltage reference. A low pass filter 108 may optionally be coupled in cascade with the unadjusted voltage reference generator 107 and configured to remove noise aliasing from unadjusted voltage reference. By coupling the unadjusted voltage reference generator 107 to ground, or coupled to an AC ground (i.e. any biasing voltage), the unadjusted voltage reference may be filtered without filtering the output of the DAC 106. A buffer 110 follows the adder and may be configured to isolate the input from the output, preventing the load, i.e. the output voltage from affecting the analog signal received from the buffer. Finally, an optional low pass filter 111 is shown after the buffer used to filter out high-frequency noise from the signal.

The output voltage 112 of the circuit is labelled V_{REF} and represents an adjusted voltage reference (as opposed to the unadjusted seed voltage reference). As mentioned above, the output voltage is fed back into the ADC and so this feedback loop allows the circuit to dynamically self-correct the output voltage.

The three calibration signals, VCAL_PNP, VCAL_NPN and VPTAT can be compared by an ADC system (the ADC and digital algorithm in FIG. 3) to a very slow-changing and unknown voltage V_{REF}.

Data stored in the look-up tables represents average values versus absolute temperature of:
VCAL_PNP-voltage across the emitter-base junction of a PNP transistor in absence of mechanical stress,
VCAL_NPN-voltage across the base-emitter junction of a NPN transistor in absence of mechanical stress,
Rₛₜᵣₑₛₛ=SΔV_{BE}^{(PNP)}/SΔV_{BE}^{(NPN)}—ratio of sensitivities to mechanical stress of the voltage across the emitter-base junction of a PNP transistor compared to the voltage across the base-emitter junction of a NPN transistor. SAVse represents the voltage shift across the junction of a BIT, induced by mechanical stress.
VPTAT—the difference between voltages across emitter-base junctions of two similar transistors biased one with high collector current density and one with low collector current density.

Through the digital algorithm (iterative or single step), the values of the three independent unknown quantities can be determined. These are:
V_{REF}—value of the voltage reference,
Tₐ—ambient junction temperature of the transistor, to be determined with accuracy better than ΔTₘₐₓ,
SΔV_{BE}^{(PNP)}—stress-induced change in the voltage across emitter-base junction of the PNP transistor, which is used to generate VCAL_PNP.

VPTAT is assumed immune to mechanical stress. This behaviour is ensured through Dynamic Element Matching (DEM).

The ADC system can generate three conversion results:

$${c}_{0} = \frac{V CAL - PNP}{{V}_{REF}} , {c}_{1} = \frac{{V}_{PTAT}}{{V}_{REF}} , {c}_{2} = \frac{VCAL\_NPN}{{V}_{REF}}$$

Once the three calibrated signals have been converted into the three conversion results, the algorithm may be embedded in a feed-back control loop used to adjust the value of V_{REF} towards a target value V_{REFTARGET} Stored in digital format during fabrication.

The operation of the control loop shown in FIG. 3 can be described as follows:

A digital algorithm may be used to determine an estimated VCAL_PNP, as a dependent output variable,

$${\tilde{V}}_{BG}^{( PNP )} = {\tilde{V}}_{REF} \cdot {c}_{0} .$$

The target ADC conversion code obtained if the estimated VCAL_PNP is measured using a target voltage reference:

$$\text{?}$$

$$\text{?} \text{indicates text missing or illegible when filed}$$

A sigma delta approach may be used to shape the noise of V_{REF}. In some examples, a first order control loop using a single digital integrator with negative feedback may be implemented as:

$${c}_{DAC} = {c}_{DAC} - g ( c {0}^{target} - c 0 ) ,$$

where g is the gain of the integrator. In one implementation,

$${c}_{DAC} = {c}_{DAC} + {Gc}_{0} ( 1 - \frac{{c}_{0}^{target}}{{c}_{0}} ) = {c}_{DAC} + {Gc}_{0} ( 1 - \frac{\frac{{\tilde{V}}_{BG}^{( PNP )}}{{V}_{REF}^{( target )}}}{\frac{{\tilde{V}}_{BG}^{( PNP )}}{{\tilde{V}}_{REF}}} ) =$$

$$= {c}_{DAC} + {Gc}_{0} ( 1 - \frac{{\tilde{V}}_{REF}}{{V}_{REF}^{( target )}} ) = {c}_{DAC} + \frac{{Gc}_{0}}{{V}_{REF}^{( target )}} ( {V}_{REF}^{( target )} - {\tilde{V}}_{REF} ) =$$

$$= {c}_{DAC} + gain \cdot {c}_{0} ( {V}_{REF}^{( target )} - {\tilde{V}}_{REF} )$$

In other examples, a second order integrator may be implemented by the control loop:

$${w}_{1} = {w}_{1} + gain \cdot {c}_{0} ( {V}_{REF}^{( target )} - {\tilde{V}}_{REF} )$$

$${w}_{2} = {w}_{2} + {w}_{1}$$

$${c}_{DAC} = 2 {w}_{1} + {w}_{2}$$

The control loop may include additional integrators to provide further noise shaping to the output voltage. Regardless of the order of the integrator, the output V_{REF} may be adjusted as follows:

$${V}_{REF} = {V}_{REF}^{( seed )} ( 1 + {c}_{DAC} )$$

It is not necessary that the control DAC uses V_{REFSEED} as an unadjusted voltage reference. If a different unadjusted voltage reference is used then:

$${V}_{REF} = {V}_{REF}^{( seed )} + {V}_{REF}^{( DAC )} {c}_{DAC}$$

The only relevant parameters of the reference for the DAC, V_{REF}, and the seed voltage reference are noise and to be changing significantly slower than the update rate of the algorithm or the DAC update rate, and the total range of this change to be smaller than the range of the DAC. In practice, c_{DAC}<<1. Therefore, the noise and variability of V_{REF(DAC)} are significantly more relaxed compared with V_{REFSEED}. As long as the ADC system runs fast enough relative to changes in V_{REFSEED}, then there is no time for noise to change (and can model the system as if there is wideband thermal noise only), then V_{REF} can be corrected, thus 1/f noise can mitigated and the impact of noise on the voltage reference is greatly reduced. The circuit of the present disclosure can achieve up to 30 dB lower noise. At the output, a low pass filter such as an RC filter can be used to remove the high frequency part of V_{REF}. For example, only signals below 500 Hz, which is still above the corner frequency of the system, which might be 10-50 Hz, may be allowed to pass. This is about an order of magnitude lower than the frequency of the DAC.

Relative to the circuit of FIG. 2, the circuit of FIG. 3 advantageously does not require a separate V ref block, thus reducing the number of voltage reference generators in this system down from two to one, i.e. just the seed voltage reference generator. Further, the MUX has 3 inputs instead of 4 inputs.

Yet further, the circuit of FIG. 2 corrects a digital voltage, i.e. the conversion result, whereas the circuit of FIG. 3 corrects V_{REF}, which is an analog value. By correcting the analog voltage output V_{REF} instead of correcting the conversion result, thus 1/f noise can mitigated using noise shaping at the output in order to lower the noise profile at low frequencies, whereas the system of FIG. 2 can only “whiten” the pink noise and mitigate the problem to some extent.

The output of the seed voltage generator in FIG. 3 might slowly drift over time, it might change with temperature, humidity, mechanical stress, voltage supply, etc. The reasons for these slow changes do not matter as such to the correction of the analog voltage output V_{REF}, as long as this change is slow enough so that the algorithm can track it and compensate for it using the DAC. What matters is that the calibration bandgap (CAL_BG) changes only due to mechanical stress and temperature, and nothing else.

The output of the DAC is affected by quantization noise. The noise of the seed voltage reference is injected in the control loop in the same point as the quantization noise of the DAC.

The techniques of the present disclosure can also be combined with other techniques for reducing variations due to temperature and mechanical stress on V_{REF}.

FIG. 4 shows a possible signal chain implementation in accordance with the present disclosure to generate the error signal.

The digital algorithm block in FIG. 4 is shown as an iterative algorithm block but in other examples it may be a single step algorithm block. It receives inputs from ADC conversions of the calibration circuit and the algorithm iteratively processes these inputs to generate estimates of various parameters. The inputs to the iterative algorithm are digital signals derived from the calibration circuit and they are converted by an ADC before being fed into the iterative algorithm. The iterative algorithm generates three outputs:
An estimate of V_REF in digital form.
An estimate of the ambient temperature (T_a) in digital form.
An estimate of the mechanical stress-induced variation in VCAL_PNP (SA/ΔR_PNP).

Following the iterative algorithm, the digital signals are added to the unadjusted seed voltage reference, multiplied, gain adjusted and integrated. The integration stage allows noise shaping of the signal before it produces the final output, which is labelled C_DAC, used as a digital code for adjusting the analog representation of the output signal to reach the ideal output signal.

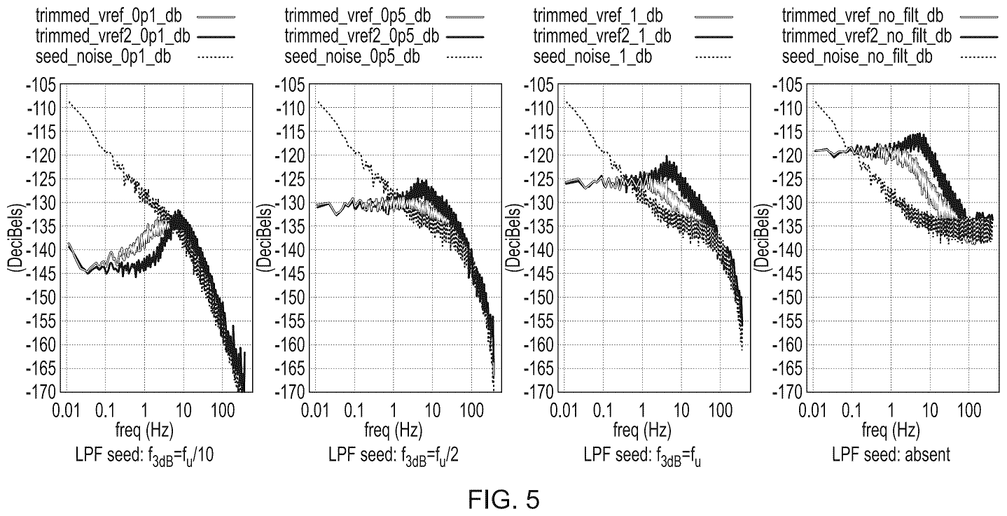

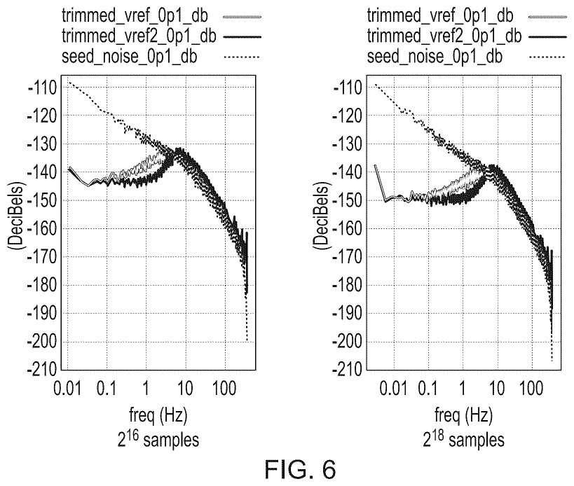

If the seed reference is not filtered, the control loop may remove 1/f noise components, but the system introduces additional noise at high frequencies as it is shown in FIGS. 5 and 6.

FIG. 5 shows four graphs that compare the spectrums of V_{REF} for various bandwidths of seed voltage generator low pass filter (LPF), where fᵤ=96 Hz—the update rate of the control DAC. The only restriction imposed on the seed voltage reference is that its output must change over time significantly slower than the DAC update rate (the need for a LPF stems from this requirement).

The graphs of FIG. 5 were each produced using 1^{st} order RC filters as the LPFs but it will be appreciated that other order RC filters may be used in different examples of the disclosure.

In each graph, the x-axis of represents frequency, labeled from 0.01 to 100 Hz on a logarithmic scale. The y-axis represents the magnitude of noise in decibels (dB), ranging from −150 to −110 dB.

Variations in the frequency response due to different seed reference generator LPFs are shown, with the “f3 dB” value indicating the cutoff frequency of the low pass filter relative to the DAC update rate ‘fᵤ’. The bandwidths of seed voltage generator low pass filter (LPF), from left to right, are as follows:

$${}^{‶} L P F seed : {f}_{3 dB} = {f}_{u} / {10}^{″}$$

$${}^{‶} L P F seed : {f}_{3 dB} = {f}_{u} / {2}^{″}$$

$${}^{‶} L P F seed : {f}_{3 dB} = {{f}_{u}}^{″}$$

$${}^{‶} L P F seed : {absent}^{″}$$

In each of the graphs, three noise profiles are shown. Blue represents the noise of seed reference generator without any integration. Green represents the noise of V_{REF} using a 1st order integrator and brown represents the noise of V_{REF} using a 2^{nd} order integrator.

These graphs are useful for analyzing the impact of LPF settings on the noise profile and therefore the signal quality at the output, V_{REF}.

FIG. 6 shows two spectral density plots, which are used to show the spectrum of V_{REF}. The spectra in the plots across represent two simulations of the proposed system when f_{3dB}=fᵤ/10. The difference between them is the total number of samples, which translates into a different frequency bin size for Fourier spectral analysis.

In each graph, the x-axis of represents frequency, labeled from 0.01 to 100 Hz on a logarithmic scale. The y-axis represents the magnitude of noise in decibels (dB), ranging from −200 to −120 dB.

In the iterative algorithm example, as the iterative algorithm exits when the three estimates converge towards their true values within a certain non-zero tolerance, a small non-zero offset will be present at the output. This offset appears as “bin zero” energy in the spectral plots. The plots use logarithmic scale for frequency and, in the logarithmic scale, “bin zero” cannot be represented.

In FIG. 6, all signals are preconditioned using a Hann window. Hann windowing in spectral analysis introduces a limited skirting effect to adjacent frequency bins. What can be seen in the plots is this skirting effect of power spilling from bin zero (not plotted) into bin one. As offset (bin zero) is very small, this effect can be observed only when the noise floor is low enough. Note that power/bin is 4 times smaller when there are 218 samples (6 dB in the plots). However, the offset is the same, and its impact on bin one is therefore identical.

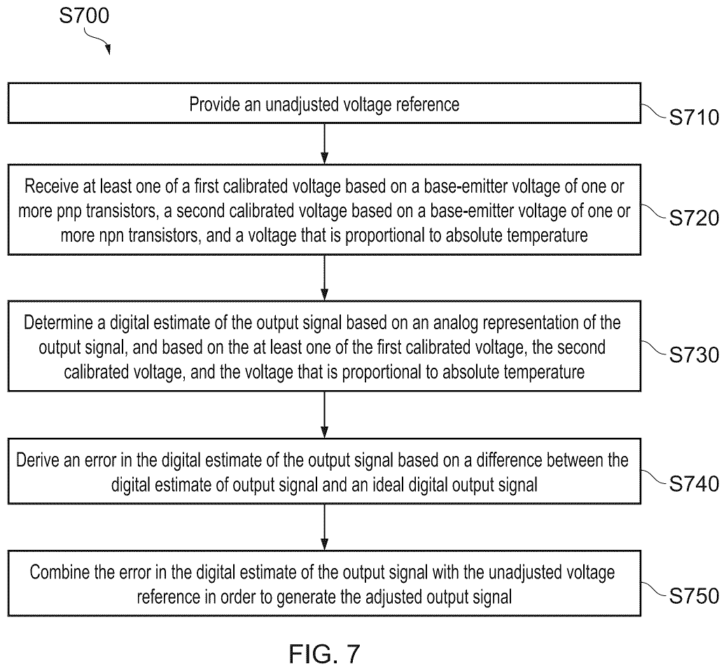

FIG. 7 represents example method steps 700 according to an aspect of the present disclosure. In general, at step S710, an unadjusted voltage reference is provided. At step S720, at least one of a first calibrated voltage based on a base-emitter voltage of one or more pnp transistors, a second calibrated voltage based on a base-emitter voltage of one or more npn transistors, and a voltage that is proportional to absolute temperature is received. At step S730, a digital estimate of the output signal is determined based on an analog representation of the output signal, and based on the at least one of the first calibrated voltage, the second calibrated voltage, and the voltage that is proportional to absolute temperature. At step S740, an error in the digital estimate of the output signal is derived based on a difference between the digital estimate of output signal and an ideal digital output signal. Finally, at step S750, the error in the digital estimate of the output signal is combined with the unadjusted voltage reference in order to generate the adjusted output signal.

The skilled person will readily appreciate that various alterations or modifications may be made to the above-described aspects of the disclosure without departing from the scope of the disclosure. For example, features of two or more of the above examples may be combined and still fall within the scope of the present disclosure.

### NUMBERED ASPECTS

By way of non-limiting example, some aspects of the disclosure are set out in the following numbered clauses.
Numbered Clause 1. A method of generating of an adjusted output signal, the method comprising:
   providing an unadjusted voltage reference;
   receiving at least one of a first calibrated voltage based on a base-emitter voltage of one or more pnp transistors, a second calibrated voltage based on a base-emitter voltage of one or more npn transistors, and a voltage that is proportional to absolute temperature;
   determining a digital estimate of the output signal based on an analog representation of the output signal, and based on the at least one of the first calibrated voltage, the second calibrated voltage, and the voltage that is proportional to absolute temperature;
   deriving an error in the digital estimate of the output signal based on a difference between the digital estimate of output signal and an ideal digital output signal; and
   combining the error in the digital estimate of the output signal with the unadjusted voltage reference in order to generate the adjusted output signal.
Numbered Clause 2. The method of Numbered Clause 1, the method comprising:
   receiving the voltage that is proportional to absolute temperature and at least one of the first calibrated voltage and the second calibrated voltage.
Numbered Clause 3. The method of Numbered Clause 2, the method comprising:
   receiving the voltage that is proportional to absolute temperature, the first calibrated voltage and the second calibrated voltage.
Numbered Clause 4. The method of any preceding Numbered Clause, wherein determining an estimate of the output signal comprises performing an iterative algorithm.
Numbered Clause 5. The method of Numbered Clause 4, wherein the iterative algorithm produces a digital code for adjusting the analog representation of the output signal to reach the ideal output signal.
Numbered Clause 6. The method of any of Numbered Clauses 1 to 3, wherein determining an estimate of the output signal comprises performing a single step algorithm.
Numbered Clause 7. The method of any preceding Numbered Clause, wherein determining a digital estimate of the output signal comprises determining a digital estimate of the at least one of the first calibrated voltage, the second calibrated voltage, and the voltage that is proportional to absolute temperature.
Numbered Clause 8. The method of any preceding Numbered Clause, further comprising:
   low pass filtering the unadjusted voltage reference in order to remove noise aliasing from unadjusted voltage reference.
Numbered Clause 9. The method of any preceding Numbered Clause, further comprising:
   shaping the noise profile of the adjusted output signal using a first order integration.
Numbered Clause 10. The method of any of Numbered Clause 1 to 8, further comprising:
   shaping the noise profile of the adjusted output signal using a second order or higher order integration.
Numbered Clause 11. A circuit for generating an adjusted output signal, the circuit comprising:
   a calibration circuit providing at least one of a first calibrated pnp voltage based on a base-emitter voltage of one or more pnp transistors, a second calibrated non voltage based on a base-emitter voltage of one or more npn transistors, and a voltage that is proportional to absolute temperature;
   an analog-to-digital converter, ADC, system coupled to the calibration circuit, and configured to:
      determine a digital estimate of the output signal based on an analog representation of the output signal, and based on the at least one of the first calibrated voltage, the second calibrated voltage, and the voltage that is proportional to absolute temperature; and
      derive an error in the digital estimate of the output signal based on a difference between the digital estimate of output signal and an ideal digital output signal;
   a digital-to-analog converter, DAC, configured to output an analog representation of the error; and
   an unadjusted voltage reference generator configured to generate an unadjusted voltage reference that is combined together with the output of the DAC in order to generate the adjusted output signal.
Numbered Clause 12. The circuit of Numbered Clause 11, wherein the calibration circuit provides the voltage that is proportional to absolute temperature and at least one of the first calibrated voltage and the second calibrated voltage.
Numbered Clause 13. The circuit of Numbered Clause 12, wherein the calibration circuit provides the voltage that is proportional to absolute temperature, the first calibrated voltage and the second calibrated voltage.
Numbered Clause 14. The circuit of any of Numbered Clauses 11 to 13, wherein the ADC system comprises:
   a multiplexer configured to provide an analog signal selected from the first calibrated pnp voltage, and the second calibrated npn voltage; and
   an ADC configured to generate a digital estimate of the analog signal selected by the multiplexer and a digital estimate of an analog representation of the output signal.
Numbered Clause 15. The circuit of any of Numbered Clauses 11 to 14, wherein the ADC system comprises a processor configured to determine the digital estimate of the output signal based on the digital estimate of the analog signal selected by the multiplexer and the digital estimate of the analog representation of the output signal.
Numbered Clause 16. The circuit of any of Numbered Clauses 11 to 15, wherein the ADC system is configured to determine a digital estimate of the output signal by performing an iterative algorithm.
Numbered Clause 17. The circuit of Numbered Clause 16, wherein the iterative algorithm produces a digital code for adjusting the analog representation output signal to reach the ideal output signal.
Numbered Clause 18. The circuit of any of Numbered Clause 11 to 15, wherein the ADC system is configured to determine an estimate of the output signal by performing a single step algorithm.
Numbered Clause 19. The circuit of any of Numbered Clause 11 to 18, wherein the ADC system is configured to determine a digital estimate of the output signal comprises determining a digital estimate of the at least one of the first calibrated voltage, the second calibrated voltage, and the voltage that is proportional to absolute temperature.
Numbered Clause 20. The circuit of any of Numbered Clauses 11 to 19, further comprising a low pass filter, coupled in cascade with the unadjusted voltage reference generator, and configured to remove noise aliasing from unadjusted voltage reference.
Numbered Clause 21. The circuit of Numbered Clause 20, wherein the bandpass of the low pass filter is an order of magnitude lower than the DAC update rate.
Numbered Clause 22. The circuit of any of Numbered Clauses 11 to 21, further comprising a digital integrator configured to shape the noise profile of the adjusted output signal.
Numbered Clause 23. The circuit of any of Numbered Clauses 11 to 22, further comprising an adder configured to sum the output of the DAC and the unadjusted voltage reference.

1. A method of generating of an adjusted output signal, the method comprising:
providing an unadjusted voltage reference;
receiving at least one of a first calibrated voltage based on a base-emitter voltage of one or more pnp transistors, a second calibrated voltage based on a base-emitter voltage of one or more npn transistors, and a voltage that is proportional to absolute temperature;
determining a digital estimate of the output signal based on an analog representation of the output signal, and based on the at least one of the first calibrated voltage, the second calibrated voltage, and the voltage that is proportional to absolute temperature;
deriving an error in the digital estimate of the output signal based on a difference between the digital estimate of output signal and an ideal digital output signal; and
combining the error in the digital estimate of the output signal with the unadjusted voltage reference in order to generate the adjusted output signal.

2. The method of claim 1, the method comprising:
receiving the voltage that is proportional to absolute temperature and at least one of the first calibrated voltage and the second calibrated voltage.

3. The method of claim 2, the method comprising:
receiving the voltage that is proportional to absolute temperature, the first calibrated voltage and the second calibrated voltage.

4. The method of claim 1, wherein determining an estimate of the output signal comprises performing an iterative algorithm.

5. The method of claim 4, wherein the iterative algorithm produces a digital code for adjusting the analog representation of the output signal to reach the ideal output signal.

6. The method of claim 1, wherein determining an estimate of the output signal comprises performing a single step algorithm.

7. The method of claim 1, wherein determining a digital estimate of the output signal comprises determining a digital estimate of the at least one of the first calibrated voltage, the second calibrated voltage, and the voltage that is proportional to absolute temperature.

8. The method of claim 1, further comprising:
low pass filtering the unadjusted voltage reference in order to remove noise aliasing from unadjusted voltage reference.

9. The method of claim 1, further comprising:
shaping a noise profile of the adjusted output signal using a first order integration, a second order or a higher order integration.

10. A circuit for generating an adjusted output signal, the circuit comprising:
a calibration circuit providing at least one of a first calibrated pnp voltage based on a base-emitter voltage of one or more pnp transistors, a second calibrated npn voltage based on a base-emitter voltage of one or more npn transistors, and a voltage that is proportional to absolute temperature;
an analog-to-digital converter, ADC, system coupled to the calibration circuit, and configured to:
determine a digital estimate of the output signal based on an analog representation of the output signal, and based on the at least one of the first calibrated voltage, the second calibrated voltage, and the voltage that is proportional to absolute temperature; and
derive an error in the digital estimate of the output signal based on a difference between the digital estimate of output signal and an ideal digital output signal;
a digital-to-analog converter, DAC, configured to output an analog representation of the error; and
an unadjusted voltage reference generator configured to generate an unadjusted voltage reference that is combined together with the output of the DAC in order to generate the adjusted output signal.

11. The circuit of claim 10, wherein the calibration circuit provides the voltage that is proportional to absolute temperature and at least one of the first calibrated voltage and the second calibrated voltage.

12. The circuit of claim 11, wherein the calibration circuit provides the voltage that is proportional to absolute temperature, the first calibrated voltage and the second calibrated voltage.

13. The circuit of claim 10, wherein the ADC system comprises:
a multiplexer configured to provide an analog signal selected from the first calibrated pnp voltage, and the second calibrated npn voltage; and
an ADC configured to generate a digital estimate of the analog signal selected by the multiplexer and a digital estimate of an analog representation of the output signal.

14. The circuit of claim 10, wherein the ADC system comprises a processor configured to determine the digital estimate of the output signal based on the digital estimate of the analog signal selected by a multiplexer and the digital estimate of the analog representation of the output signal.

15. The circuit of claim 10, wherein the ADC system is configured to determine a digital estimate of the output signal by performing an iterative algorithm.

16. The circuit of claim 15, wherein the iterative algorithm produces a digital code for adjusting the analog representation output signal to reach the ideal output signal.

17. The circuit of claim 10, wherein the ADC system is configured to determine an estimate of the output signal by performing a single step algorithm.

18. The circuit of claim 10, wherein the ADC system is configured to determine a digital estimate of the output signal comprises determining a digital estimate of the at least one of the first calibrated voltage, the second calibrated voltage, and the voltage that is proportional to absolute temperature.

19. The circuit of claim 10, further comprising a low pass filter, coupled in cascade with the unadjusted voltage reference generator, and configured to remove noise aliasing from unadjusted voltage reference, wherein a bandpass of the low pass filter is an order of magnitude lower than a DAC update rate.

20. The circuit of claim 10, further comprising a digital integrator configured to shape a noise profile of the adjusted output signal and/or further comprising an adder configured to sum the output of the DAC and the unadjusted voltage reference.
